(19) United States
(12) Patent Application Publication
(10) Pub. No.: US 2025/0031417 A1
(43) Pub. Date: Jan. 23, 2025

(54) SEMICONDUCTOR DEVICE AND METHOD FOR MANUFACTURING THE SAME

(71) Applicant: INSTITUTE OF MICROELECTRONICS, CHINESE ACADEMY OF SCIENCES, Beijing (CN)

(72) Inventors: Huaxiang YIN, Beijing (CN); Qingzhu ZHANG, Beijing (CN); Yadong ZHANG, Beijing (CN); Jiaxin YAO, Beijing (CN)

(21) Appl. No.: 18/543,652

(22) Filed: Dec. 18, 2023

(30) Foreign Application Priority Data
Jul. 21, 2023 (CN) 202310901540.6

(51) Int. Cl. H01L 29/06; H01L 21/8234; H01L 27/088; H01L 29/08; H01L 29/423; H01L 29/66; H01L 29/775; H01L 29/786

(52) U.S. Cl. CPC H01L 29/0642; H01L 21/823418; H01L 21/823437; H01L 21/823468; H01L 21/823481; H01L 27/088; H01L 29/0673; H01L 29/0847; H01L 29/42392; H01L 29/66439; H01L 29/66545; H01L 29/775; H01L 29/78696

(57) ABSTRACT

A semiconductor device and a method for manufacturing the same. The method comprise: forming a first field-effect transistor (FET) disposed on a substrate and a first isolation layer disposed on the first FET; forming a first through hole in the first isolation layer, where a metal layer is deposited in the first through hole and is electrically connected to the first FET; forming a second isolation layer, which is disposed on the first isolation layer and the metal layer; and forming a second FET which is disposed on the second isolation layer, where a second through hole is disposed in the second FET and the second isolation layer, a metal material filled in the second through hole serves as a first contact plug, and the first contact plug is electrically connected to the metal layer. The metal layer serves as a power distribution network for both FETs.

This application claims priority to Chinese Patent Application No. 202310901540.6, titled “METHOD FOR MANUFACTURING SEMICONDUCTOR DEVICE AND SEMICONDUCTOR DEVICE,” filed on Jul. 21, 2023 with the China National Intellectual Property Administration, which is incorporated herein by reference in its entirety.

### FIELD

The present disclosure relates to the technical field of semiconductor, and in particular to a semiconductor device and a method for manufacturing the same.

### BACKGROUND

With continuous development of the technology node and key techniques in integrated circuits, nanosheet gate-all-around field-effect transistors (NS GAAFETs) would replace conventional fin field-effect transistors (FinFETs) at the 3 nm and more advanced nodes. Furthermore, the next generation of three-dimensional stacked field-effect transistors (3DS FETs) would become a main technical route after entering the 1 nm node.

Currently, there are mainly two manners for achieving the 3DS FETs. One is sequential integration, and the other is self-aligned simultaneous integration. The sequential integration is simpler in processing and has more applicable materials and techniques, but is limited due to performances and costs. The self-aligned simultaneous integration can achieve a higher degree of integration and better performances, but are subject to a complicated integration process and various processing challenges.

In addition, an increasing attention has been drawn by the backside power distribution network (BS-PDN) techniques, in which a power distribution network (PDN) traditionally fabricated in a backend of line (BEOL) is disposed at a back of a wafer through appropriate processing. In comparison with the front-side power distribution network (FS-PDN), semiconductor devices manufactured through BS-PDN have a higher integration density and smaller voltage loss of a power source due to a voltage drop on interconnections. An urgent problem is how to manufacture novel semiconductor devices through combining the 3DS FETs and the PDN fabrication to increase the integration density.

### SUMMARY

In view of at least the above issues, a semiconductor device and a method for manufacturing the semiconductor device are provided according to embodiments of present disclosure. An integration density of semiconductor devices is increased with fewer fabrication processes and fewer difficulties.

In a first aspect, a method for manufacturing a semiconductor device is provided according to an embodiment of the present disclosure. The method comprises: forming a first field-effect transistor disposed on a substrate and a first isolation layer disposed on the first field-effect transistor; forming a first through hole in the first isolation layer, where a metal layer is deposited in the first through hole and is electrically connected to the first field-effect transistor; forming a second isolation layer which is disposed on the first isolation layer and the metal layer; and forming a second field-effect transistor which is disposed on the second isolation layer, where a second through hole is disposed in the second field-effect transistor and the second isolation layer, a metal material filled in the second through hole serves as a first contact plug, and the first contact plug is electrically connected to the metal layer.

In an embodiment, forming the first field-effect transistor disposed on the substrate and the first isolation layer disposed on the first field-effect transistor comprises: forming stacking layers on the substrate, where the stacking layers comprise at least one first semiconductor layer and at least one second semiconductor layer which are alternately stacked; etching the stacking layers and the substrate to form a fin, where the substrate of a partial thickness is removed in the etching; forming a dummy gate, a first spacer, and a mask layer on the fin; etching the stacking layers by using at least the first spacer as a mask; etching the at least one first semiconductor layer from a side surface of the etched stacking layers to form at least one cavity; forming at least one second spacer in the at least one cavity; forming a source and a drain at two sides of the stacking layers; forming a third isolation layer on the source and the drain; removing the dummy gate and the etched at least one first semiconductor layer to release the at least one second semiconductor layer as a channel; forming a gate surrounding the channel; forming a third through hole running in the third isolation layer, where a metal material filled in the third through hole serves as a second contact plug, and the second contact plug is configured to connect the metal layer electrically.

In an embodiment, before forming the second isolation layer which is disposed on the first isolation layer and the metal layer, the method further comprises: planarizing the metal layer until a top surface of the metal layer is flush with a top surface of the first isolation layer.

In an embodiment, a material of the metal layer comprises at least one of W, Al, Cu, Co, Ti, Pt, TiN, TaN, TiC, Mo, Ru, Au, or Ag.

In an embodiment, a thickness or width of the metal layer ranges from 1 nm to 10000 nm.

In an embodiment, the metal layer comprises only a single layer or comprises multiple layers.

In an embodiment, the first field-effect transistor and the second field-effect transistor each is a nanosheet gate-all-around field-effect transistor.

In a second aspect, a semiconductor device is provided according to embodiments of the present disclosure. The semiconductor device comprises: a first field-effect transistor, a first isolation layer, a second isolation layer, and a second field-effect transistor, which are stacked on a substrate according to the above-listed sequence; where a metal layer is disposed in the first isolation layer, the metal layer is electrically connected to the first field-effect transistor, a first contact plug is disposed in the second field-effect transistor, and the first contact plug is electrically connected to the metal layer.

In an embodiment, a material of the metal layer comprises at least one of W, Al, Cu, Co, Ti, Pt, TiN, TaN, TiC, Mo, Ru, Au, or Ag.

In an embodiment, a thickness or width of the metal layer ranges from 1 nm to 10000 nm.

The semiconductor device and the method for manufacturing the semiconductor device are provided according to embodiments of the present disclosure. The first field-effect transistor is formed on the substrate, the first isolation layer is formed on the first field-effect transistor, the first through hole is formed in the first isolation layer, and the metal layer is deposited in the first through hole to serve as a power distribution supply network. The power distribution supply network is configured to transmit power to field-effect transistors. The metal layer is electrically connected to the first field-effect transistor, and hence is capable to transmit power to the first field-effect transistor. A front-side power distribution network (FS-PDN) structure of the first field-effect transistor is formed since the first field-effect transistor and the power distribution supply network are disposed at the same side of the substrate. The second isolation layer is formed on the first isolation layer and the metal layer, and the second field-effect transistor is formed on the second isolation layer. The second through hole runs through the second field-effect transistor and the second isolation layer, and is filled with metal material to form a first contact plug. The first contact plug is electrically connected to the metal layer, such that the metal layer can transmit power to the second field-effect transistor. Thereby, a backside power distribution network (BS-PDN) structure of the second field-effect transistor is formed. The BS-PDN structure occupies little space, and can downscale the semiconductor device. In addition, the first field-effect transistor and the second field-effect transistor share the same metal layer for power supply, which improves an integration density of semiconductor devices without thinning the substrate. The whole process has fewer steps and is less difficult.

### BRIEF DESCRIPTION OF THE DRAWINGS

In order to clarity illustration of the technical solutions according to embodiments of the present disclosure or conventional technology, hereinafter the drawings to be applied in embodiments of the present disclosure or technology are briefly described. Apparently, the drawings in the following descriptions are only some embodiments of the present disclosure, and other drawings may be obtained by those skilled in the art based on the provided drawings without creative efforts.

FIG. 1 is a schematic flowchart of a method for manufacturing a semiconductor device according to an embodiment of the present disclosure.

FIG. 2 is a schematic structural diagram of a semiconductor device according to an embodiment of the present disclosure.

FIG. 3 is a schematic diagram of an overall structure of a first field-effect transistor according to an embodiment of the present disclosure.

FIG. 4 is a cross-sectional view along an X-X direction of a semiconductor device according to an embodiment of the present disclosure;

FIG. 5 is a cross-sectional view along an X-X direction of a semiconductor device according to another embodiment of the present disclosure.

FIG. 6 is a cross-sectional view along a Y-Y direction of a semiconductor device according to an embodiment of the present disclosure.

FIG. 7 is a cross-sectional view along an X-X direction of a semiconductor device according to another embodiment of the present disclosure.

FIG. 8 is a cross-sectional view along a Y-Y direction of a semiconductor device according to another embodiment of the present disclosure.

FIG. 9 is a cross-sectional view along a Y-Y direction of a semiconductor device according to another embodiment of the present disclosure.

FIG. 10 is a cross-sectional view along an X-X direction of a semiconductor device according to another embodiment of the present disclosure.

FIG. 11 is a cross-sectional view along a Y-Y direction of a semiconductor device according to another embodiment of the present disclosure.

FIG. 12 is a cross-sectional view along an X-X direction of a semiconductor device according to another embodiment of the present disclosure.

FIG. 13 is a cross-sectional view along an X-X direction of a semiconductor device according to another embodiment of the present disclosure.

FIG. 14 is a cross-sectional view along an X-X direction of a semiconductor device according to another embodiment of the present disclosure.

FIG. 15 is a cross-sectional view along a Y-Y direction of a semiconductor device according to another embodiment of the present disclosure.

FIG. 16 is a cross-sectional view along an X-X direction of a semiconductor device according to another embodiment of the present disclosure.

FIG. 17 is a cross-sectional view along a Y-Y direction of a semiconductor device according to another embodiment of the present disclosure.

FIG. 18 is a cross-sectional view along an X-X direction of a semiconductor device according to another embodiment of the present disclosure.

FIG. 19 is a cross-sectional view along a Y-Y direction of a semiconductor device according to another embodiment of the present disclosure.

FIG. 20 is a cross-sectional view along an X-X direction of a semiconductor device according to another embodiment of the present disclosure.

FIG. 21 is a cross-sectional view along a Y-Y direction of a semiconductor device according to another embodiment of the present disclosure.

FIG. 22 is a cross-sectional view along an X-X direction of a semiconductor device according to another embodiment of the present disclosure.

FIG. 23 is a cross-sectional view along a Y-Y direction of a semiconductor device according to another embodiment of the present disclosure.

FIG. 24 is a cross-sectional view along an X-X direction of a semiconductor device according to another embodiment of the present disclosure.

FIG. 25 is a cross-sectional view along a Y-Y direction of a semiconductor device according to another embodiment of the present disclosure.

FIG. 26 is a cross-sectional view along an X-X direction of a semiconductor device according to another embodiment of the present disclosure.

FIG. 27 is a cross-sectional view along a Y-Y direction of a semiconductor device according to another embodiment of the present disclosure.

FIG. 28 is a cross-sectional view along an X-X direction of a semiconductor device according to another embodiment of the present disclosure.

FIG. 29 is a cross-sectional view along a Y-Y direction of a semiconductor device according to another embodiment of the present disclosure.

FIG. 30 is a cross-sectional view along an X-X direction of a semiconductor device according to another embodiment of the present disclosure.

### DETAILED DESCRIPTION OF EMBODIMENTS

In order to elucidate and clarify objectives, features and advantages of the present disclosure, hereinafter embodiments of the present disclosure are described in detail in conjunction of the drawings.

Various details are set forth in the following description to facilitate comprehensive understanding of the present disclosure. The present disclosure may further implemented in other ways different from those described herein. Those skilled in the art can deduce other implementations without deviating from concepts of the present disclosure, and hence the present disclosure is not limited to the following embodiments.

The present disclosure is described in detail in conjunction with schematic diagrams. When describing an embodiment, a device structure may not be partially enlarged to scale in a diagram showing a cross section of such device structure, so as to facilitate illustration. The schematic diagrams are only exemplary and shall not be construed as limitations on a protection scope of the present disclosure. In practice, the device structure shall have three-dimensional dimensions, e.g., a length, a width, and a depth.

In order to facilitate understanding, hereinafter a semiconductor device and a method for manufacturing the semiconductor device according to embodiments of the present disclosure are illustrated in detail in conjunction with the drawings.

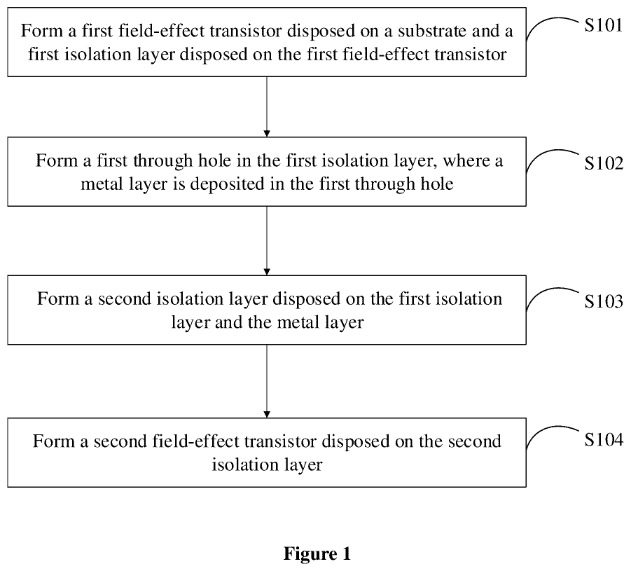

Reference is made to FIG. 1, which a schematic flowchart of a method for manufacturing a semiconductor device according to an embodiment of the present disclosure. The method comprises steps S101 to S104.

In S101, a first field-effect transistor (FET) disposed on a substrate and a first isolation layer disposed on the first field-effect transistor, are formed.

Herein a substrate may be provided, and the substrate may be Si or SiGe. The substrate may be made of bulk silicon and may be doped. In an embodiment, dopants are injected into the bulk silicon substrate, diffused, and then annealed, so as to form a highly-doped well region which has a desired well depth. In case of a p-type FET, the highly-doped well region comprises a n-type well, and injected dopants are n-type impurity ions, such as phosphorus (P) ions. In case of a n-type FET, the highly-doped well region comprises a p-type well, and injected dopants are p-type impurity ions, such as boron (B) ions.

In order to facilitate illustration, an upward direction refers to a direction pointing from the substrate to the first FET, and a downward direction refers to a direction pointing from the first FET to the substrate. Such definitions are for convenience and are not necessarily indicate a relationship with a direction of gravity.

In an embodiment, the first FET is formed on the substrate, and the first FET may be a nanosheet gate-all-around FET, or another type of FET, which is not limited herein. Then, the first isolation layer may be formed on a surface of the first FET. The first isolation layer is configured to isolate the first FET from the second FET.

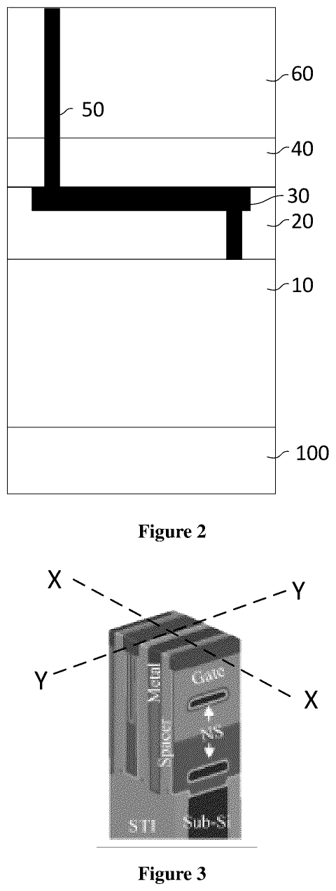

In an embodiment, the semiconductor device may be a three-dimensional stacked FET (3DS FET) or a vertical FET (VFET). The 3DS FET may be a complementary FET (CFET). It is appreciate that other types of FETs may be used. Reference is made to FIG. 2, which is a schematic structural diagram of a semiconductor device according to an embodiment of the present disclosure. The first FET 10 and the first isolation layer 20 are provided on the substrate 100.

In S102, a first through hole is formed in the first isolation layer, where a metal layer is deposited in the first through hole.

Herein a through hole formed in the first isolation layer 20 is called the first through hole. The first through hole may run through the first isolation layer 20. A shape of the first through hole is not specifically limited herein. For example, the first through hole may comprise a first portion and a second portion, which are physically connected. The first portion is disposed at a top surface of the first isolation layer 20, and a second part runs from the first portion to a bottom surface the first isolation layer 20. A lateral dimension of the first part may be larger than that of the second part. The first portion may be configured to form a power distribution supply network, and the second portion may be configured to connect the first portion and the first FET.

The metal layer 30 may be deposited in the first through hole, such that the metal layer 30 serves as the power distribution supply network and is electrically connected to the first FET 10. Thereby, the power distribution supply network can transmit power to the first FET 10. The first FET 10 and the power distribution supply network are disposed on the same side of the substrate 100, and hence an FS-PDN structure of the first FET is formed.

In an embodiment, a material of the metal layer 30 may include at least one of W, Al, Cu, Co, Ti, Pt, TiN, TaN, TiC, Mo, Ru, Au, or Ag. Hence, the metal layer has good heat resistance and low electrical resistance, which facilitate conducting a large current.

In an embodiment, a thickness of the metal layer 30 may be greater than or equal to 1 nm, and less than or equal to 10000 nm. A width of the metal layer 30 can also be greater than or equal to Inm, and less than or equal to 10000 nm. Those skilled in the art can select specific dimensions according to an actual situation.

In an embodiment, the metal layer 30 may be a single layer or comprise multiple layers, which depends on a specific circuit design. In a case that the metal layer 30 comprise multiple layers, whether the multiple layers are interconnected may be configured based on an actual situation.

In S103, a second isolation layer disposed on the first isolation layer and the metal layer is formed.

Herein the second isolation layer 40 may be formed on the first isolation layer 20 and the metal layer 30. A material of the second isolation layer 40 can be identical to or different from that of the first isolation layer 20. The second isolation layer 40 is configured to isolate the metal layer 30 form the second FET 60. After being formed, the second isolation layer 40 may be planerized through chemical-mechanical planarization (CMP).

In an embodiment, before the second isolation layer 40 is formed on the first isolation layer 20 and the metal layer 30, the metal layer 30 may be planerized until a top surface of the metal layer 30 is flush with the top surface of the first isolation layer 20. Thereby, performances of the semiconductor device are improved.

In S104, a second FET disposed on the second isolation layer is formed.

In an embodiment, the second FET 60 is formed on the second isolation layer 40. A process of manufacturing the second FET 60 may refer to that of manufacturing the first FET 10. A channel material of the second FET 60 and a channel material of the first FET 10 may be identical or different. The second FET 60 may also be a gate-all-around FET or another type of FET.

In an embodiment, a through hole may be formed in the second FET 60 and the second isolation layer 40, and is called a second through hole. The second through hole may be filled with a metal material, so as to form a first contact plug 50. The first contact plug 50 may be electrically connected to the metal layer 30, such that the metal layer 30 can further transmit power to the second FET 60. Thereby, a BS-PDN structure of the second FET is formed. The BS-PDN structure occupies less space, which reduces a dimension of the semiconductor device and increases an integration density of semiconductor devices. In addition, the first FET 10 and the second FET 60 share the same metal layer 30 for power supply, and thus it is not necessary to provide separate metal layers for the FETs, which reduces a quantity of metal layers and increases the integration density of semiconductor devices.

Herein sequential integration is adopted to manufacture the semiconductor device, and materials and processing can be selected from a variety of candidates. When manufacturing conventional BS-PDN structures, it is necessary to thin a wafer having a large thickness of approximate hundreds of microns to approximate ten to twenty microns. In technical solutions provided herein, the buried metal layer 30 is formed in the isolation layers between an upper layer and a lower layer of FETs to provide the power distribution supply network. A total thickness of the first isolation layer 20 and the second isolation layer 40 is as small as several microns or several nanometers, and thus the thinning is not necessary, which reduces steps in the processing and renders the manufacture less difficult.

Hereinafter the first FET 10 being a nanosheet gate-all-around FET is taken as an example for a brief illustration of forming the first FET 10 and the first isolation layer 20 that are sequentially stacked on the substrate 100.

Reference is made to FIG. 3, which is a schematic diagram of an overall structure of a first FET according to an embodiment of the present disclosure. In FIG. 3, two directions are defined as “X-X” and “Y-Y”, which are indicated as two dashed lines, respectively. Subsequent Figures each shows a schematic diagram of a cross section along the line X-X or the line Y-Y.

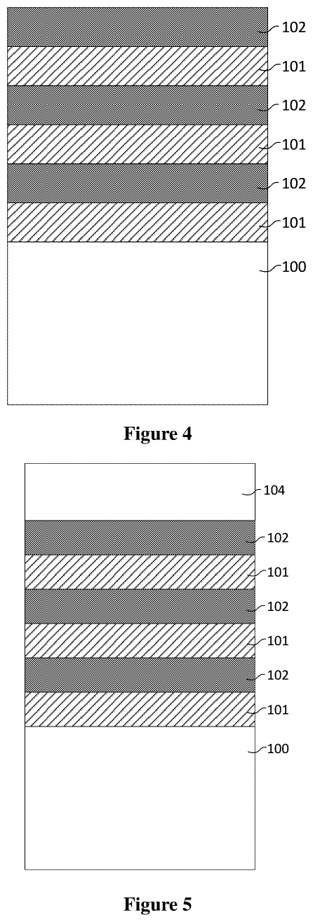

In an embodiment, stacking layers are grown through epitaxy on the substrate, and the stacking layers comprises least one first semiconductor layer and at least one second semiconductor layer which are alternately stacked. Reference is made to FIG. 4, which is a cross-sectional view of a semiconductor device along the X-X direction according to an embodiment of the present disclosure. In such step, a cross-sectional view along the Y-Y direction is substantially the same as that along the X-X direction.

In an embodiment, a material of the first semiconductor layer 101 and a material of the second semiconductor layer 102 may be configured on requirement. The first semiconductor layer 101 may be a germanium-based film. The germanium-based film may include an epitaxial germanium layer, an epitaxial silicon germanium layer, or a combination of the two. The second semiconductor layer 102 can be an epitaxial silicon layer. For example, the stacking layers of the first semiconductor layer(s) and the second semiconductor layer(s) are SiGe/Si layers, and the SiGe/Si layers are grown through epitaxy as periodic superlattice. The epitaxy may be reduced pressure epitaxy, molecular beam epitaxy, or the like.

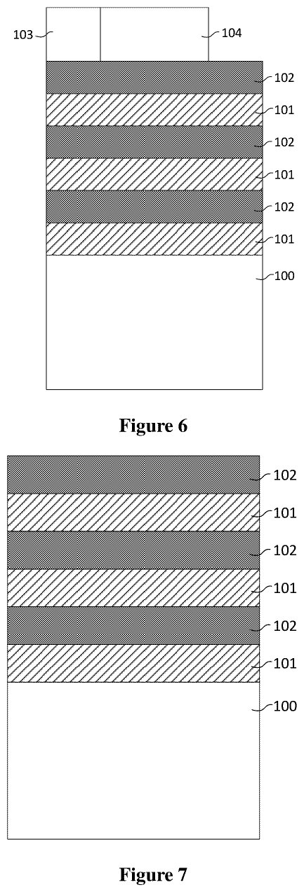

Then, the stacking layers and the substrate may be etched to form a fin, where the substrate of a partial thickness is removed during the etching. Reference is made to FIGS. 5 and 6, which show cross-sectional views of a semiconductor device along the X-X direction and the Y-Y direction, respectively, according to an embodiment of the present disclosure.

In one embodiment, a sacrificial layer 103 covering the stacking layers is formed. The sacrificial layer 103 may be made of polycrystalline silicon (PolySi, or p-si) or amorphous silicon (a-si). A part of the sacrificial layer is removed through etching, and then a third spacer 104 is deposited. The third spacer 104 may be made of silicon nitride (SiNx) or silicon oxide.

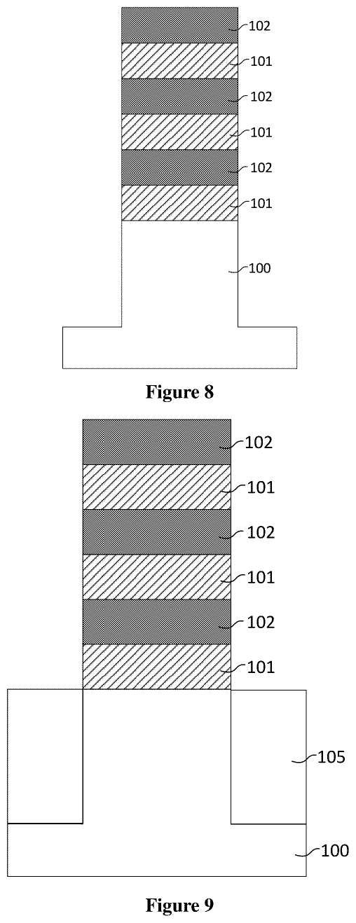

Afterwards, the remaining sacrificial layer 103 is removed through anisotropic etching, such that only the third spacer 104 remains on the stacking layers. The third spacer 104 may serve as a hard mask in subsequent photolithography. That is, the epitaxial stacking layers is then etched by using the third spacer 104 as the hard mask to form the fin which also has a stacking structure. Then, the third spacer 104 is removed, and thus the formed fin may be as shown in FIG. 7 and FIG. 8. An upper part of the fin comprises a channel region formed by the remaining stacking layers, and a lower part of the fin comprises a part of the substrate 100. That is, the fin comprises not only a structure of stacking layers 101/102, but also a structure of monocrystalline silicon originating from the substrate. The foregoing may be dry etching or wet etching, for example, may be reactive ion etching (RIE). The fin is configured to form horizontal nanosheets for an n-type FET and/or a p-type FET.

In an embodiment, shallow trench isolation (STI) 105 may be then formed around the fin, so as to separate adjacent transistors. In such step, a cross-sectional view along the Y-Y direction and a cross-section view along the X-X direction may be as shown in FIG. 9 and FIG. 7, respectively. A dielectric insulating material may be deposited and then planarized, for example, through CMP. Then, the dielectric insulating material is selectively etched to expose the three-dimensional fin structure, so as to form the shallow trench isolation 105. A top surface of the shallow trench isolation 105 may be flush or substantially flush with an interface between the stacking layers and the monocrystalline silicon substrate in the fin, or may be either higher or lower than such interface. The shallow trench isolation 105 may be made of a suitable dielectric material, such as silicon dioxide (SiO₂), silicon nitride (SiNₓ), and the like.

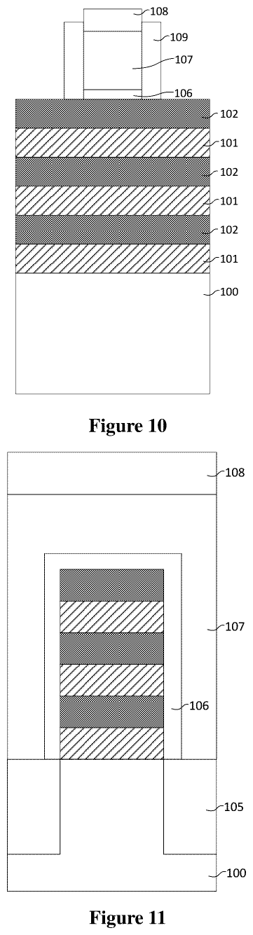

In an embodiment, a dummy gate 107, first spacers 109, and a mask layer 108 may be then formed on the fin, as shown in FIGS. 10 and 11. The dummy gate 107 may be disposed on top of the fin and extend across the stacking layer in the upper part of the fin. The dummy gate 107 may be made of polysilicon (PolySi, or p-si) or amorphous silicon (a-si). The mask layer 108 may be formed on a top of the dummy gate 107, and the first spacers 109 may be formed on two lateral sides of the dummy gate 107. The first spacers 109 may be made of silicon nitride (SiNₓ) or the like. A thickness of the first spacers 109 on both sides may be identical, and a height of the first spacer 109 may be greater than a height of the dummy gate 107 to avoid over-etching. A gate dielectric layer 106 extending across the fin may be formed before the dummy gate 107 is formed. A material of the gate dielectric layer 106 may be identical to or different from that of the shallow trench isolation 105.

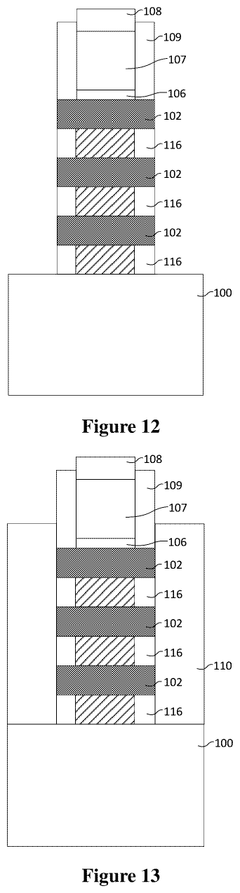

In an embodiment, the stacking layers may be then etched from its surface by using the first spacers 109 as a mask, and only the stacking layers disposed beneath the dummy gate 107 and the first spacers 109 remains after the etching. Then, the first semiconductor layer(s) 101 are etched from a side surface of the etched stacking layers, so as to form cavities at two sides of the first semiconductor layer(s), and second spacers 116 are formed in the cavities. In such step, a cross-sectional view along the X-X direction and a cross-sectional view along the Y-Y direction may be as shown in FIG. 12 and FIG. 11, respectively. In an embodiment, each first semiconductor layer 101 is etched through pull-back etching along a direction from its peripheral to its center, so that a part of the first semiconductor layer 101 is removed, and then the second spacers 116 are formed as replacement of the removed part of the first semiconductor layer 101. The second spacers 116 may be made of silicon nitride or the like.

The second spacers 116 may be formed at a periphery of the fin through deposition. After being deposited, a material for forming the second spacers 116 may be etched until it is flush with the second semiconductor layer 102 at a side surface of the fin. Thereby, the second spacers 116 are formed at two ends of the first semiconductor layer 101.

In an embodiment, a source and a drain may be then formed through epitaxy and doping. In case of a p-type FET, a material of the source and the drain may be boron-doped SiGe (SiGe: B). In case of an n-type FET, a material of the source and the drain may be phosphorus-doped silicon (Si: P). Thereby, first source-or-drain regions 110 are formed. In such step, a cross-sectional view along the X-X direction and a cross-sectional view along the Y-Y direction may be shown in FIG. 13 and FIG. 11, respectively.

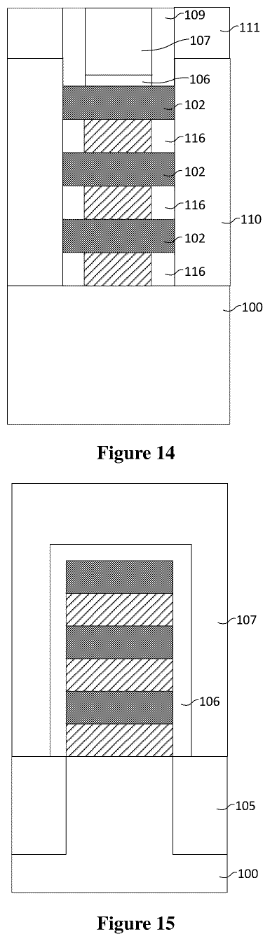

Afterwards, a third isolation layer (ILD) 111 is deposited on a surface of the first source-or-drain regions 110, as shown in FIG. 14 and FIG. 15. Thereby, interconnection or a short circuit between the dummy gate 107 and the first source-or-drain regions 110 are prevented in subsequent steps. The third isolation layer 111 may be planarized through CMP.

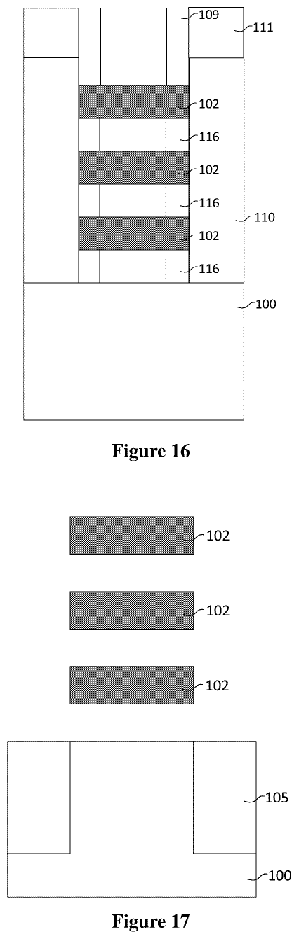

Afterwards, the dummy gate 107 mad of polycrystalline silicon (PolySi, p-si) or amorphous silicon (a-si) and the gate dielectric layer 106 made of a dielectric are selectively etched or eroded, as a shown in FIGS. 16 and 17. That is, the dummy gate 107 and the gate dielectric layer 106 are removed. The nanosheet channel is then released, that is, the first semiconductor layer(s) 101 are removed to release the second semiconductor layer(s) 102 which serve as a channel.

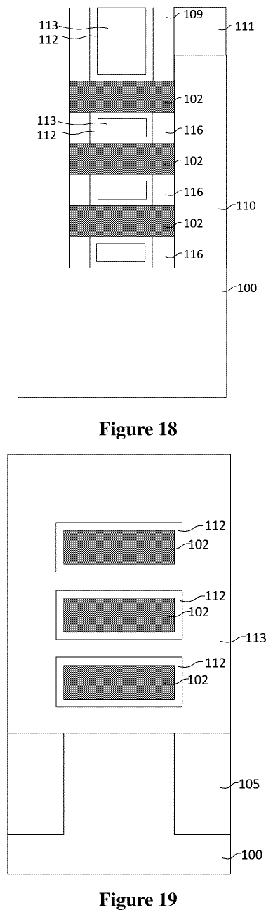

Afterwards, a first gate 113 surrounding the channel is formed, as shown in FIGS. 18 and 19. In an embodiment, a first interface oxide layer (IL) 112, a high-k dielectric layer, and a first gate 113 may be sequentially formed. The first interface oxide layer is configured to improve an interfacial characteristic between the high-k dielectric layer and the channel.

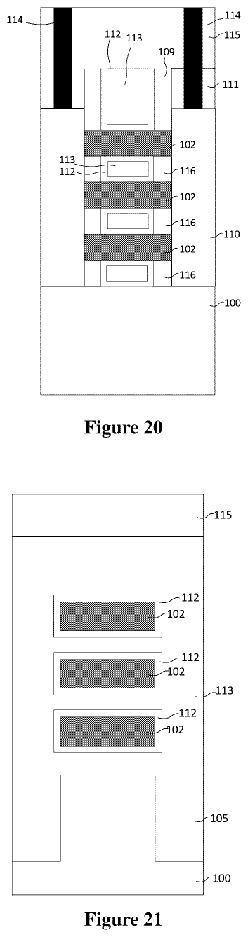

Reference is made to FIGS. 20 and 21. A fourth isolation layer 115 covering the third isolation layer 111 and the first gate 113 is deposited. Then, a third through hole 115 running through the third isolation layer 111 and the fourth isolation layer 115 may be formed. Afterwards, a metal material is deposited in the third through hole to form a second contact plug 114. An end of the second contact plug 114 is configured to connect the first source-or-drain regions 110, and another end of the second contact plug 114 is electrically connected to the metal layer 30. Thereby, electrical connection between the metal layer 30 and the first source-or-drain regions 110 can be achieved. After such step, fabrication of the first FET 10 is completed.

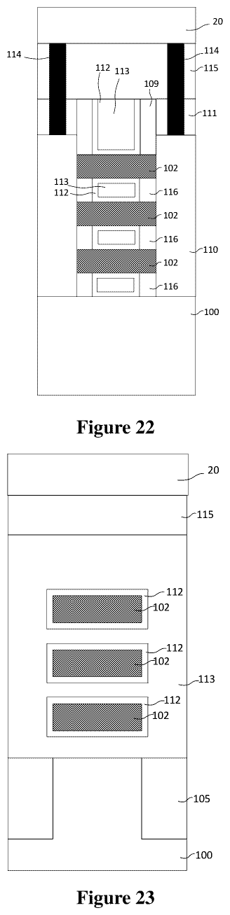

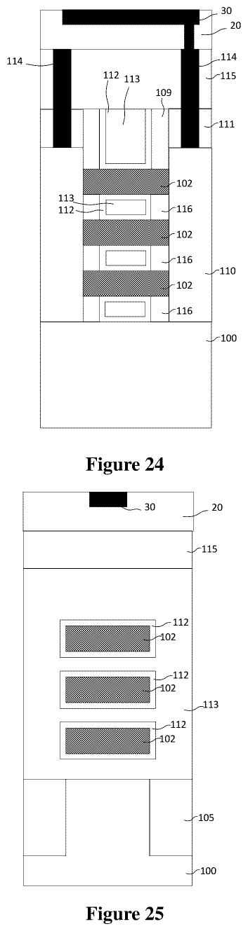

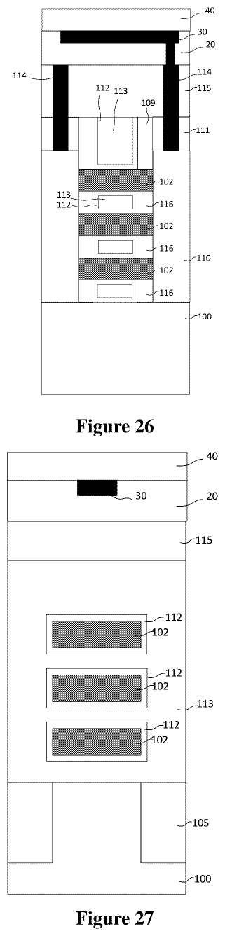

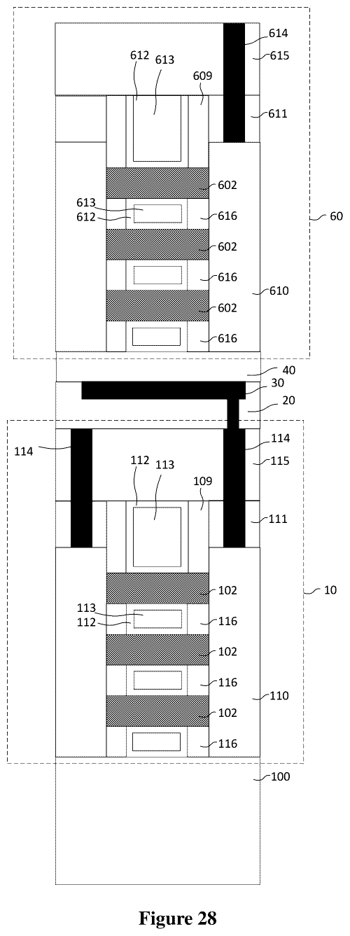

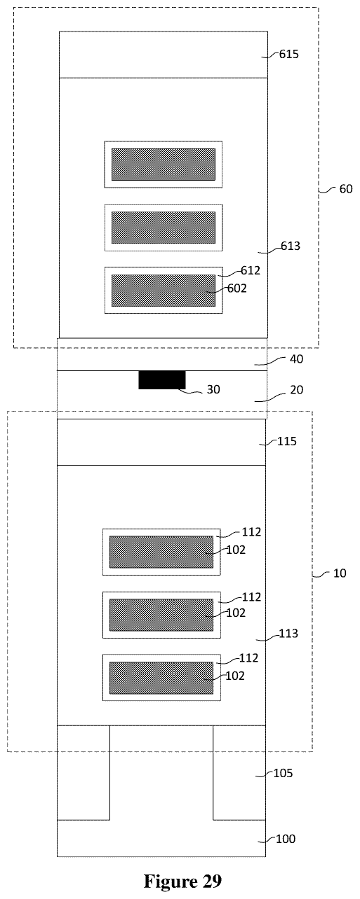

Herein the first isolation layer 20 may be deposited on the nanosheet gate-all-around FET, as shown in FIGS. 22 and 23. Then, through hole(s) may be formed in the first isolation layer 20 to obtain the first through hole, and the metal layer 30 is formed in the first through hole, as shown in FIGS. 24 and 25. The metal layer 30 serves as a power distribution network (PDN). The first FET and the PDN are interconnected through backend of line (BEOL) through hole(s), and thereby the first FET 10 below in the lower layer can be powered. Afterwards, the second isolation layer 40 is deposited, as shown in FIGS. 26 and 27. A material of the second isolation layer 40 may be identical to that of the first isolation layer 20. Then, another nanosheet gate-all-around FET is formed on the second isolation layer 40 and serves as the second FET 60, as shown in FIG. 28 and FIG. 29.

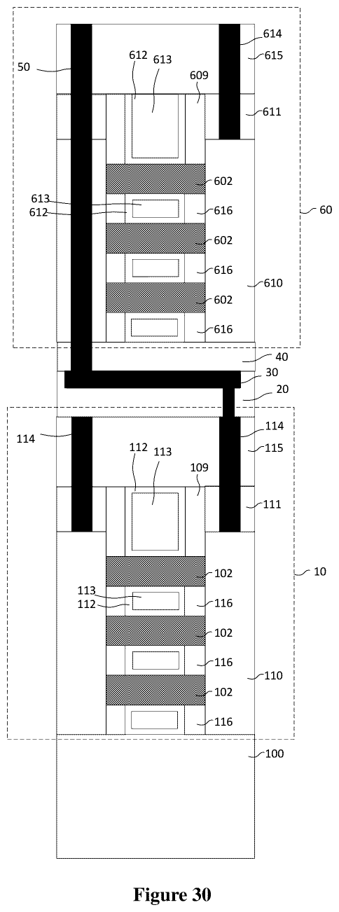

In an embodiment, the second FET 60 may comprise a third semiconductor layer 602 which serves as a channel, fourth spacers 609, fifth spacers 616, second source-or-drain regions 610, a second interface layer 612, a second gate 613, a fifth isolation layer 611, a sixth isolation layer 615, and a third contact plug 614. In order to form the third contact plug 614, the sixth isolation layer 615 and the fifth isolation layer 611 may be etched to form through hole(s) reaching the second source-or-drain region(s) 610. At the same time, the sixth isolation layer 615, the fifth isolation layer 611, the second source-or-drain regions 610 and the second isolation layer 40 may be sequentially etched to form a through silicon via (TSV), and a metal material is deposited in the TSV to form the first contact plug 50. That is, the second FET 60 and the PDN are interconnected via the TSV. A cross-sectional view of such structure along the X-X direction is as shown in FIG. 30, while a cross-sectional view of such structure along the Y-Y direction is as shown in FIG. 29. Thereby, the source and the drain can be connected to outside, and the metal layer 30 can further transmit power to the second FET 60. A degree of integration of devices is improved, and a manufacturing process has fewer steps. The TSV may be formed through laser etching or deep reactive ion etching. The TSV may be filled with polysilicon, copper, tungsten, polymer conductors, or the like. A metal material may be provided for the filling through electroplating, chemical vapor deposition, polymer coating, or another manner.

The method for manufacturing the semiconductor device is provided according to embodiments of the present disclosure. The first FET is formed on the substrate, the first isolation layer is formed on the first FET, the first through hole is formed in the first isolation layer, and the metal layer is deposited in the first through hole to serve as a power distribution supply network. The power distribution supply network is configured to transmit power to FETs. The metal layer is electrically connected to the first FET, and hence is capable to transmit power to the first FET. The FS-PDN structure of the first FET is formed since the first FET and the power distribution supply network are disposed at the same side of the substrate. The second isolation layer is formed on the first isolation layer and the metal layer, and the second FET is formed on the second isolation layer. The second through hole runs through the second FET and the second isolation layer, and is filled with metal material to form a first contact plug. The first contact plug is electrically connected to the metal layer, such that the metal layer can transmit power to the second FET. Thereby, the BS-PDN structure of the second FET is formed. The BS-PDN structure occupies little space, and can downscale the semiconductor device. In addition, the first FET and the second FET share the same metal layer for power supply, which improves an integration density of semiconductor devices without thinning the substrate. The whole process has fewer steps and is less difficult.

On a basis of the foregoing embodiment, a semiconductor device is provided according to an embodiment of the present disclosure. Reference is made to FIG. 2.

The semiconductor device may comprise a first FET 10, a first isolation layer 20, a second isolation layer 40, and a second FET 60, which are stacked on the substrate 100 according to the above-listed sequence. A metal layer 30 is disposed in the first isolation layer 20, and is electrically connected to the first FET 10. A first contact plug 50 is disposed in the second FET 60, and is electrically connected to the metal layer 30.

In an embodiment, the first FET 10 and the second FET 60 each may be a nanosheet gate-all-around FET, as shown in FIG. 30. It is appreciated that the first FET 10 and the second FET 60 each may be a transistor of another type, which is not specifically limited herein.

In an embodiment, a material of the metal layer comprises at least one of W, Al, Cu, Co, Ti, Pt, TiN, TaN, TiC, Mo, Ru, Au, or Ag.

In an embodiment, a thickness or a width of the metal layer is greater than or equal to 1 nm, and less than or equal to 10000 nm.

The semiconductor device is provided according to an embodiment of the present disclosure The semiconductor device comprises the first FET, the first isolation layer, the second isolation layer, and the second FET, which are stacked on the substrate according to the above-listed sequence. The metal layer is disposed in the first isolation layer and is electrically connected to the first FET. The first contact plug is disposed in the second FET, and is electrically connected to the metal layer. The metal layer can serve as a power distribution supply network configured to transmit power to the FETs. The metal layer is electrically connected to the first FET, and hence the metal layer can transmit power to the first FET. The FS-PDN structure of the first FET is formed since the first FET and the power distribution supply network are disposed at the same side of the substrate. The metal layer can transmit power to the second FET, and thereby the BS-PDN structure of the second FET is formed. The BS-PDN structure occupies little space, and can downscale the semiconductor device. In addition, the first FET and the second FET share the same metal layer for power supply, which improves an integration density of semiconductor devices without thinning the substrate. The whole process has fewer steps and is less difficult.

The embodiments of the present disclosure are described in a progressive manner, and each embodiment places emphasis on the difference from other embodiments. Therefore, one embodiment can refer to other embodiments for the same or similar parts. Since the semiconductor devices disclosed in the embodiments corresponds to the methods disclosed in the embodiments, the description of the semiconductor devices is simple, and reference may be made to the relevant part of the methods.

The foregoing embodiments disclosed above are only preferable embodiments of the present disclosure, and are not intended to limit the present disclosure. With the method and technical content disclosed above, those skilled in the art can make some variations and improvements to the technical solutions of the present disclosure, or make some equivalent variations on the embodiments without departing from the scope of technical solutions of the present disclosure. All simple modifications, equivalent variations and improvements made based on the technical essence of the present disclosure without departing the content of the technical solutions of the present disclosure fall within the protection scope of the technical solutions of the present disclosure.

1. A method for manufacturing a semiconductor device, comprising:
providing a substrate;
forming a first field-effect transistor disposed on a substrate and a first isolation layer disposed on the first field-effect transistor, wherein a first through hole runs through the first isolation layer, and a first metal layer deposited in the first through hole is electrically connected to a source or a drain of the first field-effect transistor;
forming a second isolation layer disposed on the first isolation layer; and
forming a second field-effect transistor disposed on the second isolation layer;
wherein a second through hole runs in the second field-effect transistor and the second isolation layer, and a second metal layer filled in the second through hole is electrically connected to the first metal layer and connected to a source or a drain of the second field-effect transistor.

2. The method according to claim 1, wherein forming the first field-effect transistor disposed on the substrate and the first isolation layer disposed on the first field-effect transistor comprises:
forming stacking layers on the substrate, wherein the stacking layers comprise at least one first semiconductor layer and at least one second semiconductor layer which are alternately stacked;
etching the stacking layers to form a fin;
forming a dummy gate on a portion of the fin, where in the dummy gate extends across the fin;
forming the source and the drain at two sides, respectively, of the fin along a first direction;
removing the dummy gate and the at least one first semiconductor layer to release the at least one second semiconductor layer as a channel; and
forming a gate stack surrounding the channel.

3. The method according to claim 2, wherein etching the stacking layers to form a fin comprises:
etching the stacking layers downward until a part of the substrate is removed.

4. The method according to claim 2, wherein before forming the source and the drain at two sides of the fin along the first direction, the method further comprises:
forming a first spacer and a mask layer, wherein the first spacer is disposed at two sides of the dummy gate along the first direction, and the mask layer is disposed at a top of the dummy gate; and
etching the fin by using the first spacer and the mask layer as a mask.

5. The method according to claim 2, wherein before forming the source and the drain at two sides of the fin along the first direction, the method further comprises:
etching the at least one first semiconductor layer from two sides of the at least one first semiconductor layer along the first direction to form cavities; and
forming a second spacer in the cavities.

6. The method according to claim 2, wherein after forming the source and the drain at two sides of the fin along the first direction, the method further comprises:
forming a third isolation layer on the source and the drain, wherein a third through hole runs through the third isolation layer, and a third metal layer filled in the third through hole is configured to connect the first metal layer with the source or the drain electrically

7. The method according to claim 1, wherein before forming the second isolation layer disposed on the first isolation layer, the method further comprises:
planarizing the first metal layer until a top surface of the first metal layer is flush with a top surface of the first isolation layer.

8. The method according to claim 1, wherein a material of the first metal layer comprises at least one of W, Al, Cu, Co, Ti, Pt, TiN, TaN, TiC, Mo, Ru, Au, or Ag.

9. The method according to claim 1, wherein a thickness or a width of the first metal layer ranges from 1 nm to 10000 nm.

10. The method according to claim 13, wherein the first metal layer comprises only a single layer or comprises a plurality of layers.

11. The method according to claim 1, wherein the first field-effect transistor and the second field-effect transistor each is a nanosheet gate-all-around field-effect transistor.

12. A semiconductor device, comprising:
a substrate;
a first field-effect transistor disposed on a substrate;
a first isolation layer disposed on the first field-effect transistor, wherein a first through hole runs through the first isolation layer, and a first metal layer deposited in the first through hole is electrically connected to a source or a drain of the first field-effect transistor;
a second isolation layer disposed on the first isolation layer; and
a second field-effect transistor disposed on the second isolation layer;
wherein a second through hole runs in the second field-effect transistor and the second isolation layer, and a second metal layer filled in the second through hole is electrically connected to the first metal layer and connected to a source or a drain of the second field-effect transistor.

13. The semiconductor device according to claim 12, wherein a material of the first metal layer comprises at least one of W, Al, Cu, Co, Ti, Pt, TiN, TaN, TiC, Mo, Ru, Au, or Ag.

14. The semiconductor device according to claim 12, wherein a thickness or a width of the first metal layer ranges from 1 nm to 10000 nm.
